(19) United States
(12) Patent Application Publication
(10) Pub. No.: US 2022/0279669 A1
(43) Pub. Date: Sep. 1, 2022

(54) SELF-SERVICE TERMINAL DEVICE

(71) Applicant: ELO TOUCH SOLUTIONS, INC., MILPITAS, CA (US)

(72) Inventors: Jinfeng ZHANG, SHANGHAI (CN); Xueqing WEI, SHANGHAI (CN); Hua SHAO, SHANGHAI (CN)

(73) Assignee: ELO TOUCH SOLUTIONS, INC., MILPITAS, CA (US)

(21) Appl. No.: 17/616,384

(22) PCT Filed: May 21, 2020
(86) PCT No.: PCT/US2020/033951

§ 371 Date: Dec. 3, 2021

(30) Foreign Application Priority Data
Jun. 27, 2019 (CN) 201910563987.0

(51) Int. Cl. H05K 5/02; H05K 5/03

(52) U.S. Cl. CPC H05K 5/0221; H05K 5/03

(57) ABSTRACT

A self-service terminal device includes a housing, an operation screen, and functional devices disposed inside the self-service terminal device. The housing includes at least one openable cover body each provided with at least one button. The at least one button is configured to manipulate a latching mechanism for the cover body of a corresponding functional device so as to open or close the corresponding cover body. In this way, the self-service terminal device can be maintained efficiently in a safe and reliable manner.

### TECHNICAL FIELD

The present invention relates to the technical field of self-service. More specifically, the present invention relates to a self-service terminal device.

### BACKGROUND

At present, with the popularization of network and the promotion of electronic payment means, many self-service terminal devices that can be operated by customers themselves substantially with no assistance from staff, for example, a self-service checkout terminal device on which a checkout operation is performed by the customers, have been developed in retailing, catering and other industries. These self-service terminal devices reduce labor costs, provide convenience for the customers and save their time.

The self-service terminal device is typically composed of a housing, an operating screen, and functional devices disposed inside the self-service terminal device. These functional devices typically include a controller, a power supply unit, a printing device, a scanning device, a microphone, and the like. With a continuous increase in the functions, the self-service terminal device is integrated with more and more functional devices, which brings a lot of troubles to routine maintenance. Thus, how to simplify the routine maintenance, increase work efficiency and improve user experience are technical problems that need to be solved urgently.

### SUMMARY

Thus, one object of the present invention is to provide a self-service terminal device capable of overcoming at least one drawback in the prior art.

According to a first aspect of the present invention, a self-service terminal device is described, comprising: a housing, an operation screen, and functional devices disposed inside the self-service terminal device, wherein the housing includes at least one openable cover body each assigned with at least one button, wherein the at least one button is configured to manipulate a latching mechanism for the cover body of a corresponding functional device in order to open or close the corresponding cover body. According to the present invention, the routine maintenance of the self-service terminal device can be simplified, the work efficiency is increased, and the user experience is improved.

In some embodiments, the functional devices inside the self-service terminal device include at least one of: a printing device, a scanning device, a control device, a voice device, a computer host, an AC connector, and a DC conversion board.

In some embodiments, the cover body includes a first cover body for a printing paper receiver of the printing device, and the first cover body is assigned with at least one first button configured to manipulate the first latching mechanism for the first cover body.

In some embodiments, the first cover body is disposed below the operation screen of the self-service terminal device.

In some embodiments, the first button is disposed on a lower wall portion, an upper wall portion, or a side wall portion of the housing.

In some embodiments, the first latching mechanism is operated and controlled such that the first cover body can be opened or closed automatically.

In some embodiments, the first latching mechanism includes a relay switch, a lock head, and a spring element, wherein when the relay switch is electrified, the lock head is retracted and the spring element causes the first cover body to spring open.

In some embodiments, the cover body includes a second cover body for exposing the interior of the self-service terminal device.

In some embodiments, the second cover body is assigned with at least one second button configured to manipulate a second latching mechanism for the second cover body.

In some embodiments, the second button is disposed on a lower wall portion, an upper wall portion, or a side wall portion of the housing.

In some embodiments, the second button is disposed in an interior space of the print paper receiver for the printing device.

In some embodiments, the second latching mechanism is operated and controlled such that the second cover body can be opened or closed automatically.

In some embodiments, the second latching mechanism includes a relay switch, a lock head, and a spring element, wherein when the relay switch is electrified, the lock head is retracted and the spring element causes the second cover body to spring open.

In some embodiments, an unlocking portion for unlocking the second cover body is provided in an interior space of the printing paper receiver for the printing device, and the latching mechanism may be unlocked manually.

In some embodiments, the button is configured as a mechanical button, a touch button, or a fingerprint button.

In some embodiments, the button is tactilely and/or visually distinct from the housing.

In some embodiments, the material of the button is different from the material of the housing; and/or the color of the button is different from the color of the housing.

In some embodiments, the housing further includes at least one power supply interface configured to power a corresponding latching mechanism to open the corresponding cover body.

In some embodiments, the at least one power supply interface may be connected to a power supply unit to receive electric energy from the power supply unit.

In some embodiments, the power supply unit includes at least one of: a portable battery, a battery, a computer, and a mobile phone.

According to a second aspect of the present invention, a self-service terminal device is described, comprising: a housing, an operation screen, and functional devices disposed inside the self-service terminal device, wherein the housing includes at least one openable first cover body for a corresponding functional device and a first latching mechanism fitted with the first cover body, the at least one openable first cover body being each assigned with at least one first button, wherein the at least one first button is configured to manipulate the first latching mechanism for the first cover body to open or close the corresponding first cover body, wherein the housing further includes at least one openable second cover body and a second latching mechanism fitted with the second cover body, the at least one openable second cover body being each assigned with at least one second button to open or close the corresponding second cover body, wherein the desired frequency for opening the first cover body is higher than the desired frequency for opening the second cover body. Here, the expression “desired frequency for opening” indicates the number of times the corresponding cover body needs to be opened statistically or probabilistically per unit time in routine maintenance.

In some embodiments, the functional devices inside the self-service terminal device include at least one of: a printing device, a scanning device, a control device, a voice device, a computer host, an AC connector, and a DC conversion board.

In some embodiments, the at least one openable first cover body includes a cover body for a printing paper receiver of the printing device.

In some embodiments, the first button and/or the second button are/is disposed on a lower wall portion, an upper wall portion or a side wall portion of the housing.

According to a third aspect of the present invention, a self-service terminal device is described, comprising: a housing, an operation screen, and functional devices disposed inside the self-service terminal device, wherein the housing includes at least one openable first cover body for a corresponding functional device and a first latching mechanism fitted with the first cover body, the at least one openable first cover body being each assigned with at least one first button, wherein the at least one first button is configured to manipulate the first latching mechanism for the first cover body to open or close the corresponding first cover body, wherein the housing further includes at least one openable second cover body and a second latching mechanism fitted with the second cover body, the at least one openable second cover body being each assigned with at least one unlocking portion to open or close the corresponding second cover body, wherein the desired frequency for opening the first cover body is higher than the desired frequency for opening the second cover body. Here, the expression “desired frequency for opening” indicates the number of times the corresponding cover body needs to be opened statistically or probabilistically per unit time in routine maintenance.

In some embodiments, the functional devices inside the self-service terminal device include at least one of: a printing device, a scanning device, a control device, a voice device, a computer host, an AC connector, and a DC conversion board.

In some embodiments, the at least one openable first cover body includes a cover body for a printing paper receiver of the printing device.

In some embodiments, the first button is disposed on a lower wall portion, an upper wall portion, or a side wall portion of the housing, and the unlocking portion is disposed in an interior space of a printing paper receiver for the printing device.

### BRIEF DESCRIPTION OF THE DRAWINGS

The drawings constituting a part of the description describe the embodiments conforming to the present invention, and accompany the description for explaining the principles of the present invention.

The present invention may be understood more clearly from the following detailed description with reference to the drawings, in which:

FIG. 1 shows a schematic outside view of a self-service terminal device according to one or more exemplary embodiments of the present disclosure;

FIG. 2 is a schematic perspective view of the self-service terminal device of FIG. 1 with the first cover body open;

FIG. 3 is a schematic perspective view of the self-service terminal device of FIG. 1 with the second cover body open.

### DETAILED DESCRIPTION

Embodiments of the present invention will be described below with reference to the drawings, in which several embodiments of the present invention are shown. It should be understood, however, that the present invention may be implemented in many different ways, and is not limited to the example embodiments described below. In fact, the embodiments described hereinafter are intended to make a more complete disclosure of the present invention and to adequately explain the scope of the present invention to a person skilled in the art. It should also be understood that, the embodiments disclosed herein can be combined in various ways to provide many additional embodiments.

It should be understood that, the wording in the specification is only used for describing particular embodiments and is not intended to limit the present invention. All the terms used in the specification (including technical and scientific terms) have the meanings as normally understood by a person skilled in the art, unless otherwise defined. For the sake of conciseness and/or clarity, well-known functions or constructions may not be described in detail.

The singular forms “a/an” and “the” as used in the specification, unless clearly indicated, all contain the plural forms. The words “comprising”, “containing” and “including” used in the specification indicate the presence of the claimed features, but do not preclude the presence of one or more additional features. The wording “and/or” as used in the specification includes any and all combinations of one or more of the relevant items listed.

In the specification, words describing spatial relationships such as “up”, “down”, “left”, “right”, “forth”, “back”, “high”, “low” and the like may describe a relation of one feature to another feature in the drawings. It should be understood that these terms also encompass different orientations of the apparatus in use or operation, in addition to encompassing the orientations shown in the drawings. For example, when the apparatus in the drawings is turned over, the features previously described as being “below” other features may be described to be “above” other features at this time. The apparatus may also be otherwise oriented (rotated 90 degrees or at other orientations) and the relative spatial relationships will be correspondingly altered.

It should be understood that, in all the drawings, the same reference signs present the same elements. In the drawings, for the sake of clarity, the sizes of certain features may be modified.

Embodiments of the present invention will now be described in more detail with reference to the accompanying drawings, in which exemplary embodiments are described.

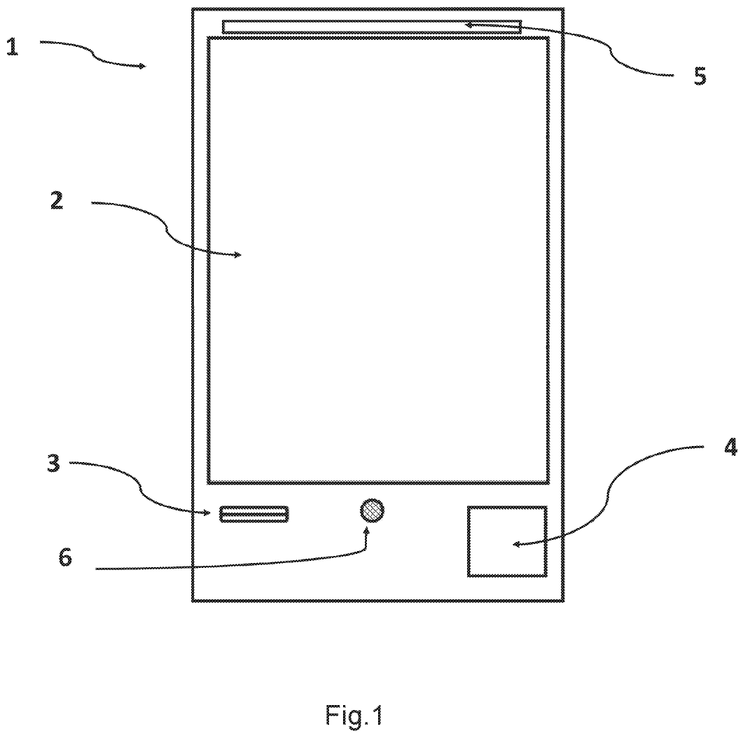

FIG. 1 shows a schematic outside view of a self-service terminal device according to one or more exemplary embodiments of the present disclosure. As shown in FIG. 1, the self-service terminal device 1 is equipped with an operation screen 2 in the form of a touch screen, a paper discharge port 3 for a printing device, a scanning window 4 for a scanning device, a light strip 5, and a microphone 6. Of course, the components for the self-service terminal device 1 are not limited thereto, and may be increased or decreased as required. For example, the self-service terminal device 1 may further include other functional devices with different functions, such as a camera, a weighing frame, a speaker, a degaussing device, a card payment device, and the like.

The operation screen 2 may be used to display a user interface of the self-service and allow interaction with a user. The self-service terminal device 1 may control, based on this interaction, the operations of the functional devices such as the printing device, the scanning device, the light strip 5, the microphone 6 and the like to thereby achieve self-service for the user. The printing device may be used to print a voucher such as a shopping receipt. The scanning device may be used to scan and read various identification marks such as two-dimensional codes, barcodes and the like. The light strip 5 may indicate the state of the self-service terminal device 1 by light color and lighting mode, wherein the lighting mode may include a flash mode, a breathing mode, and/or a constant-light mode. For instance, in the case where an error occurs during self-service of the customer and staff assistance is needed, the light strip 5 may be set in the flash mode and/or set to red to attract the staff's attention more to thereby shorten the waiting time of the customer. In the case where the self-service terminal device 1 is in an idle state, the light strip 5 may be set in the breathing mode so that the customer can figure out the available self-service device more quickly. The microphone 6 may capture the user's voice input so as to perform voice control or other operations.

The self-service terminal device 1 as shown in FIG. 1 may be used for various purposes (e.g. self-service checkout, self-service printing of receipts, self-service registration, self-service consultation, etc.) in various industries (e.g. retailing, catering, hotels, medicals, entertainment, or transportation industries). Common examples include Automatic Teller Machine (ATM), supermarket self-checkout machines, Ticket Vending Machines (TVM), and the like. Of course, the applications of the self-service terminal device 1 are not limited thereto. Instead, the self-service terminal device 1 may be used in various self-service occasions where no staff operation is required, and the functional devices allocated thereto may also vary depending on the specific application occasion.

However, with the continuous increase in the functions of the self-service terminal device, more and more functional devices are integrated, which brings a lot of troubles to the routine maintenance. Accordingly, how to simplify the routine maintenance, increase work efficiency and improve user experience are technical problems that need to be solved urgently.

In the routine maintenances, the functional devices need for frequent maintenance. Taking the printing device as an example only, staff need to frequently add printing paper to keep normal operation of the printing apparatus so as to maintain a good user experience. In conventional self-service terminal devices, the corresponding cover body is usually opened by the staff with a specially duplicated key so as to allow printing paper to be added to the printing device. However, the conventional maintenance means bring about a series of drawbacks: First, the key is easy to lose, which makes the cover body unable to be opened in time and accordingly may affect the user experience; second, the key is generally kept by specific staff, so that maintenance cannot be performed efficiently, which may affect the maintenance efficiency; Third, each of the cover bodies needs to be provided with a key opening, which may affect the appearance of the device.

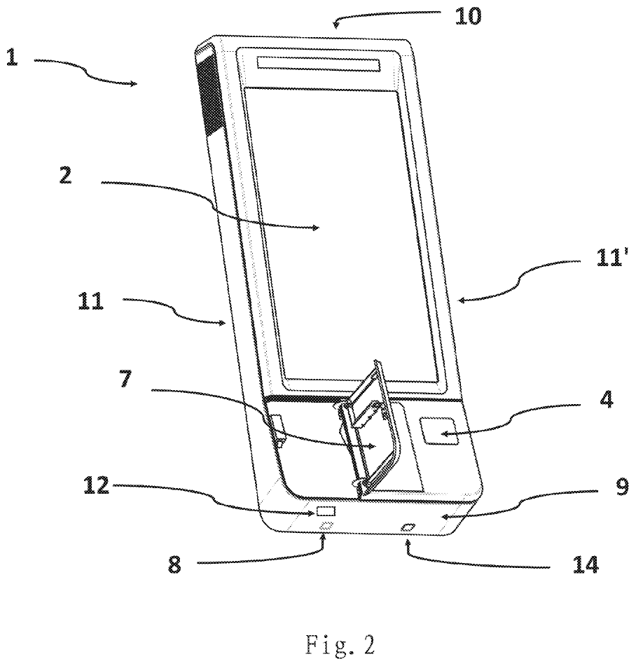

Next, a schematic perspective view of the self-service terminal device 1 of FIG. 1 with the first cover body 7 open will be further shown with reference to FIG. 2.

As shown in FIG. 2, a first cover body 7 for a printing paper receiver of the printing device is provided below the operation panel 2 of the self-service terminal device 1. The first cover body 7 may be provided with one or more first buttons 8. The first button 8 is configured to manipulate a first latching mechanism (not shown) for the first cover body 7 in order to open or close the corresponding first cover body 7. In the current embodiment, the first button 8 is not disposed on a customer-facing side of the self-service terminal device 1. Advantageously, the first button 8 may be disposed on a lower wall portion 9 of the housing of the self-service terminal device 1. This advantageously avoids the unintentional touch by the customer and improves the appearance of the device, since the button is substantially invisible to the customers. In other embodiments, the first button 8 may also be disposed on an upper wall portion 10 or a side wall portion 11, 11′ of the housing. It is also possible that the first button 8 may be disposed on a front or a rear surface of the housing.

In the current embodiment, the first latching mechanism may include a relay switch, a lock head, and a spring element. When the first button 8 is touched, a microcontroller electrically connected with the first button 8 detects this touch and thus transmits an excitation signal (e.g., an excitation signal in the form of a pulse) to the relay switch. When the relay switch is applied with the excitation signal, the lock head is retracted so that the spring element causes the first cover body 7 to spring open. In other embodiments, the first latching mechanism may also have any other feasible design. The above embodiment is merely for illustrative, not limiting, purpose.

In other embodiments, the first latching mechanism may be constructed such that the first cover body 7 can be opened or closed automatically. The first latching mechanism may include a motor and a transmission mechanism. When the first button 8 is touched, the microcontroller electrically connected with the first button 8 detects this touch and thus sends an excitation signal to control the motor to rotate. A rotation shaft of the motor is mechanically connected with the transmission mechanism, which is further mechanically connected with the first cover body 7. In this way, the first cover body 7 is automatically opened or closed depending on the touch of the first button 8. In the current embodiment, only one first button 8 may be provided. When the first cover body 7 is in the closed state, a touch of the first button 8 may cause the first cover body 7 to be opened; when the first cover body 7 is in the open state, a touch of the first button 8 may cause the first cover body 7 to be closed. Of course, the first cover body 7 may also be closed manually. In other embodiments, more first buttons 8, for example, two first buttons 8, may also be provided. Touching one of the first buttons 8 may cause the first cover body 7 to be opened, while touching the other first button 8′ may cause the first cover body 7 to be closed.

Advantageously, a first power supply interface 12 for powering the first latching mechanism may be provided on the housing such that the first cover body 7 can be opened in the event of emergency such as a fault or a power failure. As described above, once the first latching mechanism, such as the relay switch therein, is applied with an excitation signal (e.g., a DC pulse signal), the first cover 7 may spring open. Here, the first power supply interface 12 may be connected with the power supply unit through a cable to receive electric energy from the power supply unit. Advantageously, the first power supply interface 12 may be constructed as a USB interface to acquire the required electric energy from, for example, a portable battery, a battery, a computer or a mobile phone via the cable. This mode of handling in case of emergencies is particularly advantageous because the database or code in the self-service terminal device 1 often needs urgent updating, and if a fault occurs at this time to disable normal operation of the device, a major accident will be brought about. By additionally providing the power supply interface, the corresponding cover body can be opened in a timely and convenient manner, thereby allowing maintenance such as replacing the functional device, updating the code, or the like, to be performed efficiently.

In the current embodiment, the first button 8 may be configured as a mechanical button, a touch button or a fingerprint button. The mechanical button may be constructed as a common button, which may for example, protrude from a surface of the housing or be recessed into the surface of the housing. The touch button may be constructed as a capacitance-inductance touch button, an acoustic-inductance touch button or the like. The fingerprint button works based on the fingerprint of a specific personnel. The mechanical button and the touch button do not need specific personnel to be operated, which simplifies the difficulty of routine maintenance, improves maintenance efficiency, and improves user experience. Therefore, the cover bodies of the safety-noncritical functional devices such as the light strip 5 or the microphone 6 may be equipped with the mechanical button or the touch button, whereas the fingerprint button may be mainly used for safety-critical functional devices, such as the scanning device or the like. In this way, the maintenance efficiency is improved and the safety of the device is ensured.

Further, in order to be easily identifiable without affecting the aesthetics of the housing, the first button 8 may be configured to be tactilely and/or visually distinct from the housing. For example, the material of the first button 8 may be different from the material of the housing. Advantageously, the first button 8 may have its surface subjected to special treatments (such as surface roughness treatment, surface granularity treatment) so as to be tactilely distinct from the housing. It is also possible that the color of the surface of the first button 8 may be distinct from the color of the housing. Of course, it is also possible to provide a mark around the first button 8 to facilitate identification.

In the present invention, the first cover body 7 is mainly configured as a cover body for the functional device, particularly as a cover body that needs to be opened at a high frequency in daily use. In the current embodiment, the first cover body 7 is configured as a cover body for the printing device. In other embodiments, other first cover bodies 7 may also be present, which may be used, for example, for the light strip 5, the microphone 6, or the scanning device. In this way, the respective functional devices can be maintained locally, even in the case of the device being in operation, with no need to open the entire device and stop the device from running.

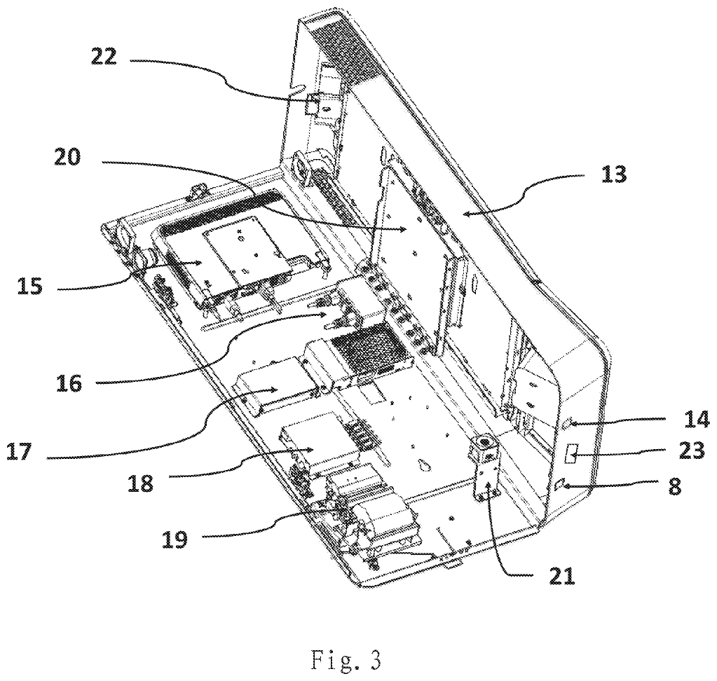

Next, FIG. 3 further shows a schematic perspective view of the self-service terminal device 1 with the entire interior being exposed. Here, the cover body for covering/exposing the interior of the self-service terminal device 1 is referred to as a second cover body 13, that is, the second cover body 13 is configured to expose the internal space of the self-service terminal device such that the internal space of the self-service terminal device is accessible from the outside.

As shown in FIG. 3, a plurality of functional devices are provided inside the self-service terminal device. A computer host 15, an AC connector 16, a DC conversion board 17, a controller 18, a printing device 19, a display stand 20, a scanning device 21, a camera 22 and the like are exemplarily shown in FIG. 3. These functional devices are integrated inside the self-service terminal device 1 and cooperate with each other. Of course, the functional devices are not limited thereto, and may include more devices.

The second cover body 13 may be assigned with one or more second buttons 14. In this case, the second button 14 is configured to manipulate a second latching mechanism (not shown) for the second cover body 13 so as to open or close the corresponding second cover body 13.

In the current embodiment, the second button 14 may be disposed on the lower wall portion of the housing of the self-service terminal device 1 similarly to the first button 8. Advantageously, the second button 14 may also be disposed in the interior space of the printing paper receiver for the printing device. In this case, only when the first cover body 7 is opened, can the second button 14 be accessed. This advantageously avoids the unintentional touch by the customer and improves the appearance of the device, as the button is substantially invisible to the customers (that is, the concealment is enhanced). In other embodiments, the second button 14 may also be disposed on the upper wall portion or the side wall portion of the housing. It is also possible that the first button 14 may be disposed on the front or rear surface of the housing.

In the current embodiment, the second latching mechanism may include a relay switch, a lock head, and a spring element. When the second button 14 is touched, a microcontroller electrically connected with the second button 14 detects this touch and thus transmits an excitation signal (e.g., an excitation signal in the form of a pulse) to the relay switch. When the relay switch is applied with the excitation signal, the lock head is retracted so that the spring element promotes the second cover body 13 to spring open. In other embodiments, the first latching mechanism may also have any other feasible design. The above embodiment is merely for illustrative, not limiting, purpose.

In other embodiments, the second latching mechanism may be constructed such that the second cover body 13 can be opened or closed automatically. Here, the second latching mechanism may include a motor and a transmission mechanism. When the second button 14 is touched, the microcontroller electrically connected with the second button 14 detects this touch and thus sends an excitation signal to manipulate the motor to rotate. Here, a rotation shaft of the motor is mechanically connected with the transmission mechanism, which is further mechanically connected with the second cover body 13. In this way, the second cover body 13 is opened or closed automatically depending on the touch of the second button 14. In the current embodiment, only one second button 14 may be provided. When the second cover body 13 is in the closed state, a touch of the second button 14 may cause the second cover body 13 to be opened; when the second cover body 13 is in the open state, a touch of the second button 14 may cause the second cover body 13 to be closed. In other embodiments, more second buttons 8, for example, two second buttons, may also be provided. Touching one of the second buttons 14 may cause the second cover body 13 to be opened, while touching the other of the second buttons 14′ may cause the second cover body 13 to be closed. Advantageously, the second cover body 13 may be opened or closed in a vertical direction, thereby saving space and avoiding collisions with the surrounding environment. In addition, the automatic operation and control of the second cover body 13 is particularly advantageous because the second cover body 13 is generally large in area and weight, and its automatic opening or closing can effectively reduce the difficulty of maintenance.

In other embodiments, the second latching mechanism may also be unlocked manually. For example, an unlocking portion (for example, a plug) for the second latching mechanism may be provided in the internal space of the printing paper receiver for the printing device, and when the first cover body 7 is opened, a manual operation of the unlocking portion can spring open the second cover body 13. This unlocking means is also particularly advantageous in that: firstly, the unlocking portion for unlocking the second latching mechanism is kept concealed and is invisible from the outside; secondly, the operational safety of the device is improved; furthermore, the available space is fully utilized, making the device more compact and effective.

Advantageously, a second power supply interface 23 for powering the second latching mechanism may be provided on the housing or in the internal space exposed by the first cover body 7, so that the second cover body 13 can be opened in the event of emergency such as a fault or a power failure. The specific implementation modes will not be described herein.

In the current embodiment, the second button 14 may be configured as a mechanical button, a touch button or a fingerprint button. Further, in order to be easily identifiable without affecting the aesthetics of the housing, the second button 14 may be configured to be tactilely and/or visually distinct from the housing. For example, the material of the second button 14 may be different from the material of the housing. Advantageously, the second button 14 may have its surface subjected to special treatments (such as surface roughness treatment, surface granularity treatment) so as to be tactilely distinct from the housing. It is also possible that the color of the surface of the second button 14 may be distinct from the color of the housing. Of course, it is also possible to provide a mark around the second button 14 to facilitate identification.

Although some specific embodiments of the present invention have been described in detail by way of example, those skilled in the art should understand that the above examples are for illustrative purposes only and are not intended to limit the scope of the present invention. The various embodiments disclosed herein may be combined in any combination without departing from the spirit and scope of the invention. It should also be understood by those skilled in the art that various modifications may be made in the embodiments without departing from the scope and spirit of the invention.

1. A self-service terminal device, comprising:
a housing, an operation screen, and functional devices disposed inside the self-service terminal device,
wherein the housing includes at least one openable cover body, at least one of which is assigned with at least one button, and
wherein the at least one button is configured to manipulate a latching mechanism for the cover body of a corresponding functional device in order to open or close the corresponding cover body.

2. The self-service terminal device according to claim 1, wherein the functional devices inside the self-service terminal device include at least one of: a printing device, a scanning device, a control device, a voice device, a computer host, an AC connector, and a DC conversion board.

3. The self-service terminal device according to claim 1, wherein the cover body includes a first cover body for a printing paper receiver of a printing device, and the first cover body is assigned with at least one first button configured to manipulate a first latching mechanism for the first cover body.

4. The self-service terminal device according to claim 3, wherein the first cover body is disposed below the operation screen of the self-service terminal device.

5. The self-service terminal device according to claim 3, wherein the first button is disposed on a lower wall portion, an upper wall portion, or a side wall portion of the housing.

6. The self-service terminal device according to claim 3, wherein the first latching mechanism is operated and controlled such that the first cover body is capable of being opened or closed automatically.

7. The self-service terminal device according to claim 3, wherein the first latching mechanism includes a relay switch, a lock head, and a spring element, and when the relay switch is electrified, the lock head is retracted and the spring element causes the first cover body to spring open.

8. The self-service terminal device according to claim 1, wherein the cover body includes a second cover body for exposing the interior of the self-service terminal device.

9. The self-service terminal device according to claim 8, wherein at least one second button is provided for the second cover body, the second button being configured to manipulate a second latching mechanism for the second cover body.

10. The self-service terminal device according to claim 9, wherein the second button is disposed on a lower wall portion, an upper wall portion or a side wall portion of the housing.

11. The self-service terminal device according to claim 9, wherein the second button is disposed in an interior space of the print paper receiver for the printing device.

12. The self-service terminal device according to claim 9, wherein the second latching mechanism is operable and controllable such that the second cover body is capable of being opened or closed automatically.

13. The self-service terminal device according to claim 9, wherein the second latching mechanism includes a relay switch, a lock head, and a spring element, and when the relay switch is electrified, the lock head is retracted and the spring element causes the second cover body to spring open.

14. The self-service terminal device according to claim 8, wherein an unlocking portion for unlocking the second cover body is provided in an interior space of a printing paper receiver for the printing device, the unlocking portion capable of being unlocked manually.

15. The self-service terminal device according to claim 1, wherein the button is configured as a mechanical button, a touch button, or a fingerprint button.

16. The self-service terminal device according to claim 1, wherein the button is tactilely and/or visually distinct from the housing.

17. The self-service terminal device according to claim 16, wherein the material of the button is different from the material of the housing; and/or the color of the button is different from the color of the housing.

18. The self-service terminal device according to claim 1, wherein the housing further includes at least one power supply interface configured to power a corresponding latching mechanism to open the corresponding cover body.

19. The self-service terminal device according to claim 18, wherein the at least one power supply interface is capable of being connected to a power supply unit to receive electric energy from the power supply unit.

20. The self-service terminal device according to claim 19, wherein the power supply unit includes at least one of: a portable battery, a battery, a computer, and a mobile phone.

21-28. (canceled)
